(19) United States
(12) Patent Application Publication
(10) Pub. No.: US 2008/0191260 A1
(43) Pub. Date: Aug. 14, 2008

(54) Semiconductor Device And Use Thereof

(75) Inventors: Leonardus Cornelis Nicolaas De Vreede, Delft (NL); Lis Karen Nanver, Delft (NL); Koen Buisman, Delft (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/576,811

(22) PCT Filed: Sep. 26, 2005
(86) PCT No.: PCT/IB05/53171

§ 371 Date: Feb. 1, 2008

(30) Foreign Application Priority Data
Oct. 5, 2004 (EP) 04104873.7

(51) Int. Cl. H01L 29/94

(52) U.S. Cl. 257/312; 257/E29.344

(57) ABSTRACT

The semiconductor device comprises a first and a second varactor which are connected in an anti-series configuration. This connection is done such that a first, substantially electrically conductive region is present between a second region with dopant of a first conductivity type and a third region with dopant of the first conductivity type. The second and third regions comprise dopant that is distributed uniformly within the region. The first region is provided with or connected to a contact which has an AC resistance of at least 1 kΩ.

The invention relates to devices for use in variable impedance matching.

Impedance matching is an important requirement in the front end of mobile telephones. It is carried out, particularly, between the antenna and the amplifiers—both low—noise amplifiers for a received signal and power amplifiers for a transmitted signal. It has the aim to transform the antenna impedance to the desired impedance levels of the in- and output stage. When properly matched the input stage provides the highest sensitivity and the output stage maximum power. In practical situations, however, the required output power is not constant. When the mobile phone is operated close to a base station the required transmitted power is much lower. For this reason, in these situations, the transmitted output power of the mobile is reduced in order to save on the battery power consumption. Although some battery saving is achieved in this way, the output stage will work in a less efficient mode of operation under these low output power conditions. This can be explained by the fact that the loading impedance offered by the matching network to the output stage transistor is fixed. Since this loading condition has been optimized for the maximum power-out operation, it is less ideal when operating the output stage under low output power conditions. This situation can be improved if the matching network would be adaptive, or in other words that it can adapt its impedance transformation to the required output power conditions.

When considering the receive mode, the presence of an adaptive matching network can be used to change the receiving band in a frequency selective way, or to avoid saturation of the input stage in the case of very high input levels. In both output and input matching the losses of the matching network should be minimized and the matching network should not degrade the signals by non-linear distortion.

Impedance matching networks are known per se in the art, and comprise a number of passive components.

In the present evolution of the art of impedance matching, two trends are visible. The first trend is towards the above mentioned adaptive impedance matching. Such adaptive impedance matching is beneficial to wideband communication, such as that implemented according to the UMTS or wideband CDMA protocols. In view of the high-frequency application, this trend is bound to the requirement of good linearity; as in the power amplifiers the third-order intermodulation distortion in particular must be suppressed so as to achieve spurious-free dynamic range over the frequency domain of interest

The solutions offered range in the use of switches. Examples hereof are pin-diodes and pHEMT devices. However, these switches have a relatively poor compatibility with mainstream technologies typically in use for high-volume RF applications. In addition, pin diodes require relatively high currents. The use of this type of switches furthermore increases the noise level of the circuitry significantly.

The second trend is towards integration of components, so as to reduce assembly costs, to allow an integrated design of the front end and to be able to provide additional functionality. This is particularly desired in view of the tendency of broader and more communication protocols. In order to achieve this goal, much research work is carried out on micro-electromechanical system (MEMS) components. These MEMS components can be used both as variable capacitors and as switches. Therewith, they do not allow only variable impedance matching, but also the integration of band switching within the front end and impedance matching. However, MEMS components require a high driving voltage and tend to give distortion if the beam is not present in one of the extreme positions. Additionally, the manufacture and packaging of MEMS components is not very cheap as a consequence of the large number of process steps needed for the manufacture of the beam and of an adequate package.

It is therefore an object of the invention to provide a variable capacitance that is suitable for impedance matching, has a good linearity over the required power range and frequency domain within the complete capacitance tuning range, and can be integrated with other devices in the front-end area on a single substrate.

This object is achieved in a semiconductor device comprising a first and a second varactor, which are connected in an anti-series configuration, such that a first substantially electrically conductive region is present between a second region with dopant of a first conductivity type and a third doped region, wherein:

the second and third regions comprise dopant that is distributed uniformly within the region, and

the first region is provided with a contact having an AC resistance of at least 1 kΩ to the control voltage source for the capacitance value.

According to the invention, use is made of a system of varactors in an anti-series configuration as the variable capacitance. Such system—also referred to as a varactor stack—is known per se for instance for use in oscillators. However, the known varactor stack does not fulfill the requirements needed for use in the RF front end.

The linearity requirement is basically dependent on the continuous path for the RF current flowing through the stack. This current is basically alternating and carries the—RF modulated—signal. The current flows from the contact at the second region to that of the third region. Now it has been found that that the alternating current flowing through the contact of the first region must be negligible in comparison to the above mentioned current. Only then is the intermodulation distortion reduced and is thus the linearity improved. As a result, the device of two varactor diodes or MOS capacitors is thus symmetrical around this contact to the first region—hereinafter also referred to as the center contact. In the ideal case, the intermodulation distortion of the varactor diodes will be completely cancelled. Such cancellation occurs not just for a certain frequency, but over the complete frequency domain.

These requirements are met in the device of the invention, in that the continuous path is optimized for the linearity, and that the center contact is provided with a high resistance. Thereto, the change in the doping profile between the first region and the other regions should be abrupt and the first region should be substantially electrically conductive. In addition, the doping level is uniform in the second and third regions to prevent any negative effects on the linearity. Additionally, the contact resistances between the second and third regions and their contacts should be low.

The varactors in the varactor stack may be varactor diodes. In that case, the first and the second region, as well as the first and the third region, have a mutual interface, which forms a junction. Alternatively, use can be made of MOS varactors, in which an electrically insulating layer is present between the first region and the second region, as well as between the first region and the third region. The thickness of the insulating layer is at most about 50 nm, above which the insulating layer will negatively affect the thickness of the depletion area in the second and third regions. There is no lower limit for the thickness of the insulating layer. Preferably, the insulating layer is thin so as to reduce the amount of charge that can be accumulated in the insulating layer. Principally, the first varactor may be of the MOS type and the second varactor of the diode type. In view of the difference in diffusion voltages between the two types of devices, cancellation of the intermodulation distortion cannot be achieved as easily as with a symmetrical device construction.

Although the term ‘junction’ may not be correct for the description of the latter embodiment, it is used herein for both embodiments. Even if an insulating layer is present between the above mentioned regions of the device, the dopant profile is nevertheless sufficiently abrupt.

The abruptness of the junctions is preferably such that the junctions have a thickness in which the dopant profile changes from the uniform doping level of the first conductivity type to the uniform doping level of the second conductivity type, which thickness is at most 50 nm and preferably less than 20 nm. It is important for the linearity that the contact provides high ohmic conditions for the RF signals. This can be achieved by making the contact itself high Ohmic, or by adding an external resistor or high ohmic controlled current source with an AC impedance in excess of 1 kΩ for the frequencies of interest.

The center contact has then the function of tuning the capacitance between the external contacts. Charging or discharging the “floating node” between the varactors controls the capacitance of the varactor stack. Due to the high impedance for the center contact, loading with alternating current (AC loading) is prevented. Such AC loading of this contact will obstruct the self-compensating operation for the non-linear distortion.

This loading can be modified statically, but also dynamically. In a situation of dynamic loading, the load line will vary with the amplitude modulation. This is particularly suitable when the varactor stack is integrated in an impedance matching network. The resistance furthermore assures that the parasitics of the control voltage will be small, in view of the substantial reduction of the current by the resistor.

The resistor is at least 1 kΩ, and more preferably in the order of 10 kΩ or more. Such resistors can be implemented as layers of CrSi, preferably comprising 5-50 at % Cr, 10-70 at % Si, 5-50 at. % O and at least one compound selected from the group consisting of boride, carbide and nitride in the concentration of 1-50 at %. An alternative, interesting resistor comprises 40-95 at % of carbon, 4-60 at % of one or more metals, particularly Ag, Pt, Au and/or Cu, and 1-30 at % of hydrogen, where no carbide-formation has occurred. These resistors allow the provision of a high resistance in combination with a relatively low temperature coefficient, particularly in the range between −100 and +100 ppm/K. It is particularly suitable that the resistor is integrated in the contact area of the first region.

It is known per se to apply varactors for tuning applications, as is described in the article of Galt et al., ‘Microwave tuning quality and power handling of voltage-tunable capacitors: semiconductor varactors versus Ba₁₋ₓSrₓTiO₃ films’, Mat. Res. Soc. Symp. Proc. vol 493 (1998), 341-346. The disclosed varactors have an abrupt junction; however, there is no disclosure of the specific construction of the device of the invention with a high impedance center contact and a low-ohmic first region. It is exactly this high impedance that makes that the varactors behave linearly since it makes the center tap current neglectable compared to the RF current flowing through the varactor stack, which is a condition for the desired cancellation of the intermodulation distortion.

In a preferred embodiment, the junctions of the first and the second diode have junction areas that are in a mutual ratio of at most two. This leads to a proper cancellation of the distortion components. It is in fact not possible to load or discharge one of the diodes selectively. Hence, there is a need, in order to prevent threshold effects and the like, that the loading of the diodes occurs in the same manner. With the provision of the control voltage in the middle between two capacitances that are of substantially equal size, this is achieved.

The ratio is preferably smaller than 1.5 and most preferably is the difference within 10%.

For this combination of effects, it is necessary for the first region to have a higher dopant concentration than the second and third regions so that an ohmic resistance is formed between the junctions of the first and the second diode. It has been found highly preferably by the inventors that the ratio of the doping level of the first region to that of the second and third regions is at least 50 and preferably more than 100. Suitably, the ratio is less than 1000. The minimum ratio allows a sufficient breakdown voltage, whereas the maximum allows a sufficient linearity.

The varactor stack may be provided in a lateral arrangement and in a vertical arrangement. The advantage of the vertical arrangement is the short path through the first region, and therewith a low series resistance and a good RF behavior. The advantage of the lateral arrangement is the simple contacting.

In a preferred embodiment, the third region is grounded. The device is single-ended as a result, contrary to varactor-stacks that are used in differential oscillators for frequency tuning. This single-ended topology is particularly useful for the adaptive impedance matching between PA and antenna since most antennas in mobile applications are single-ended by definition. This results from the superior linearity properties of the device of the invention, that are based on its single ended implementation and the high-ohmic AC connection conditions for the contact to the first region.

The low-ohmic contact is particularly a contact with a resistance of less than 10⁻⁶ Ωcm/, and preferably in the range of 0.3-3.10⁻⁷ 10⁻⁶ Ωcm/. Particularly in the case where the vertical arrangement of the varactor stack is used, there are some further implementations. A first implementation is the provision of a highly doped substrate layer. Alternatively, the third region is connected to a metal contact directly, or through a short path through the substrate only. Such a contact may be achieved by the provision of a vertical interconnect through the substrate. Such a vertical interconnect may be provided with dry-etching or a combination of dry-etching and wet-etching, and subsequent filling with conductive material, particularly based on a polysilicon seed layer and an electroplated layer thereon.

A further alternative for the provision of a low-ohmic contact to the third region that is present at the substrate is the local substrate removal. This may be realized by etching from the second side of the substrate, optionally preceded by a grinding or polishing step. The etching is suitably carried out with wet-chemical etching; in case that a silicon substrate is used, KOH is suitable as an etchant. This process is simplified by the use of a silicon-on-insulator substrate, since the insulator layer can act as an etch stop layer. This is, however, not strictly necessary, particularly in view of the fact, that the varactor stack is preferably defined in epitaxial layers on the first side of the substrate. The protection of this area through a mesa, which contains a highly doped contact area, is then suitable.

It is advantageous that the first, second and third regions are present in a substrate of semiconductor material, said substrate having a resistivity of at least 500 Ω/cm, preferably more than 1 kΩ/cm, and even more preferably of more than 3 kΩ/cm. The use of a substrate with a high resistivity reduces both capacitive losses and inductive losses. Whereas the inductive losses tend to be most important for inductors and striplines, substantial capacitive loading of the center contact would have a negative impact on the distortion of the varactor stack of the present invention.

The varactor stack of the present invention can be used in combination with other passive components as a resonator in a balun, as an electronic tuner, as a phase shifter and otherwise. Particularly the option of continuous dynamic tuning without any significant additional distortion allows a plurality of applications. It is, however, preferred to use the varactor stack as part of an impedance matching network for high frequencies.

The present varactor stack allows a tuning range of about 2.5 for instance between 8 and 20 pF in combination with a low series resistance and minimal distortion. Furthermore, breakdown levels required for use in impedance matching in mobile phones can be met. These breakdown levels are of the order of some Volts or more, and for some applications of the order of 10-15 V. The breakdown voltage is herein basically positively affected through lowering of the uniform doping in the second and the third region, while the layer thickness is increased.

In a further embodiment, the device comprises a third and a fourth varactor that form a second varactor stack similar to the first one. These varactor stacks are connected in series. This leads to an increase of the tuning range and an improvement of the voltage handling capabilities. Especially the breakdown voltage per varactor is increased. In this case of a series implementation of a varactor stack, appropriate biasing of the individual varactors should be applied with a sufficiently high impedance level for the intermediate diode contacts. Only then will the Q factor of the combination of both varactor stacks be identical with the Q-factor of a single varactor diode with the same voltage control range. Minor drawbacks of this series configuration are a higher area consumption for a given capacitance and a somewhat higher complexity in fabrication or mask layout.

In another embodiment, use is made of wide bandgap materials for the second and third regions. With such materials, an even more uniform doping level can be achieved than in silicon. This uniform doping level diminishes the number of weak points at which breakdown may occur. In order to have a very good uniformity it is highly preferable for at least the second and third regions, but preferably also the first region, to be grown epitaxially.

In a further embodiment, the first and second varactor elements are present within a substrate area that is isolated from other areas of the substrate. Such isolation prevents that any charge carriers will flow through the substrate, particularly if the substrate is high-ohmic, i.e. has a high resistivity as explained above. The diffusion of charge carriers would be detrimental to the operation of transistors and diodes present elsewhere in the substrate. Embodiments for the isolation include wells of the first conductivity, type and layers with the aim of recombining charge carriers. Alternatively, use can be made of an oxide box around the substrate area. Such an oxide box can be achieved with a combination of a ring-shaped, vertical trench in the substrate and a buried oxide layer. In addition thereto, e-beam irradiation and the inclusion of metal particles in the substrate may counteract the distribution of charge carriers.

More preferable, particularly with such isolation, is the presence of pin diodes in the same substrate as the varactor diodes. Despite the above problems of pin diodes to be used in adaptive impedance matching, these components are very suitable for use as band switches. Both vertical and lateral pin diodes can be applied. Vertical pin diodes currently behave better, but have the disadvantage of awkward contacting. Moreover, the design of lateral pin diodes can easily be amended for each individual pin diode. The size of the pin diode, and particularly of the zones thereof, can then be made dependent on the frequency band of its intended use. The combination of the varactor stack as variable capacitance and the lateral pin diodes as switches allows the creation of an integrated network for impedance matching and band switching. Obviously, the number of band switches is not limited to one as a result, but can be increased so as to make divisions between receive and transmit bands and between bands of different frequencies. The impedance matching network could further comprise a balun, if so desired.

In a suitable embodiment, the first region comprises a recombination layer of a material different from other layers in the first region. The recombination layer of a different material effectively reduces the necessary thickness of the first region. Suitable materials for the recombination layer include SiGe and Al.

The device of the invention is suitably embodied on a substrate of silicon and with epitaxially grown layers of silicon, and optionally SiGe or Al. It is, however, not excluded that wideband materials are used, such as GaAs, AlGaAs and InP. Moreover, the substrate may be removed partially or substantially completely after processing, and other substrates may be used that allow the epitaxial growth of the first, second and third regions.

These and other aspects of the invention will be further elucidated with reference to the figures, in which:

FIG. 1 shows a diagrammatic cross-sectional view of a first arrangement of the device of the invention;

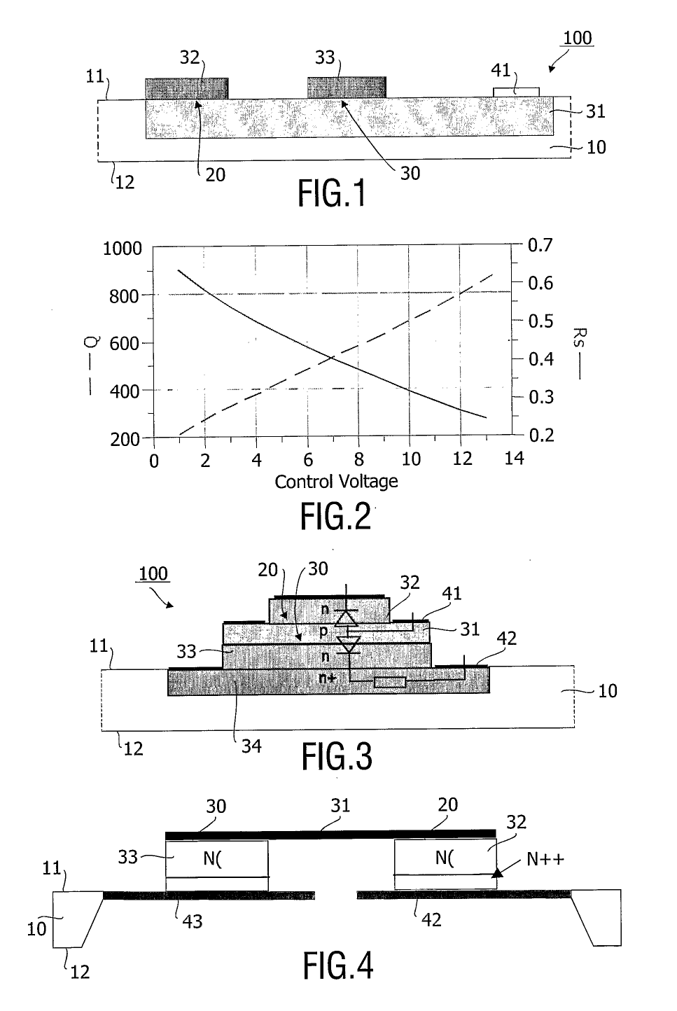

FIG. 2 is a graph in which the Q-factor and series resistance versus Control Voltage are shown for the device as shown in FIG. 1;

FIG. 3 shows a diagrammatic cross-sectional view of a second arrangement of the device of the invention;

FIG. 4 shows a diagrammatic cross-sectional view of a third arrangement of the device of the invention;

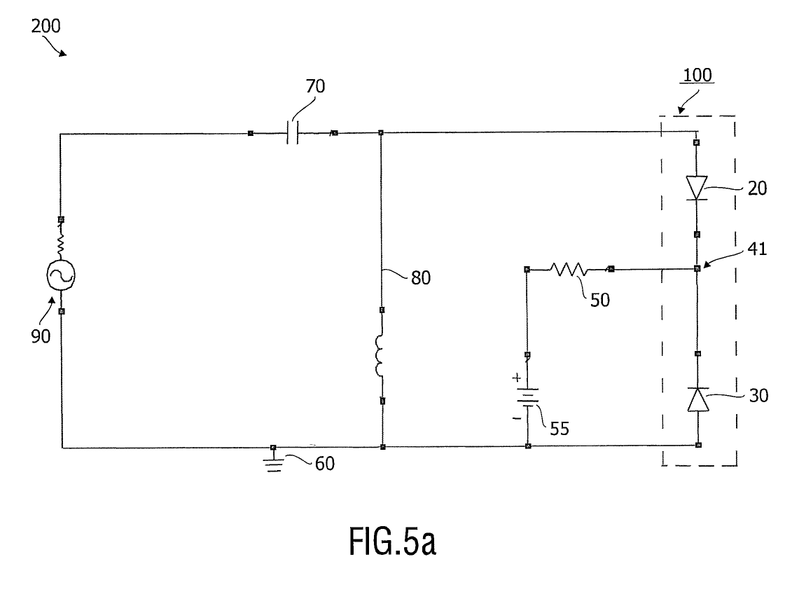

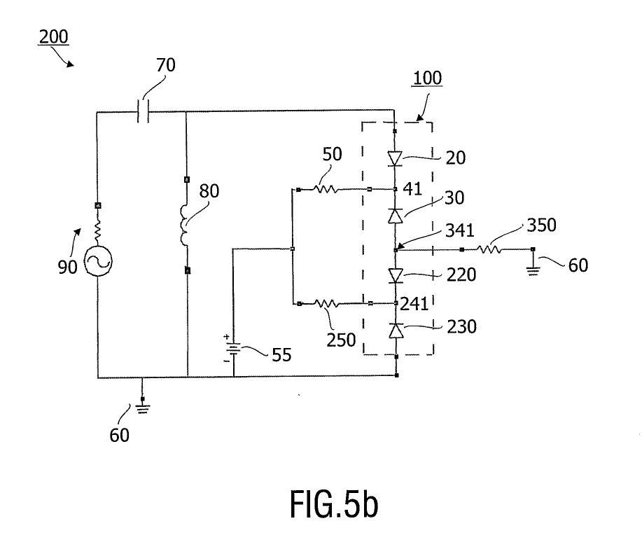

FIG. 5a shows an electrical configuration of a varactor stack;

FIG. 5b shows the electrical configuration when two varactor stacks are combined to improve the voltage handling capabilities;

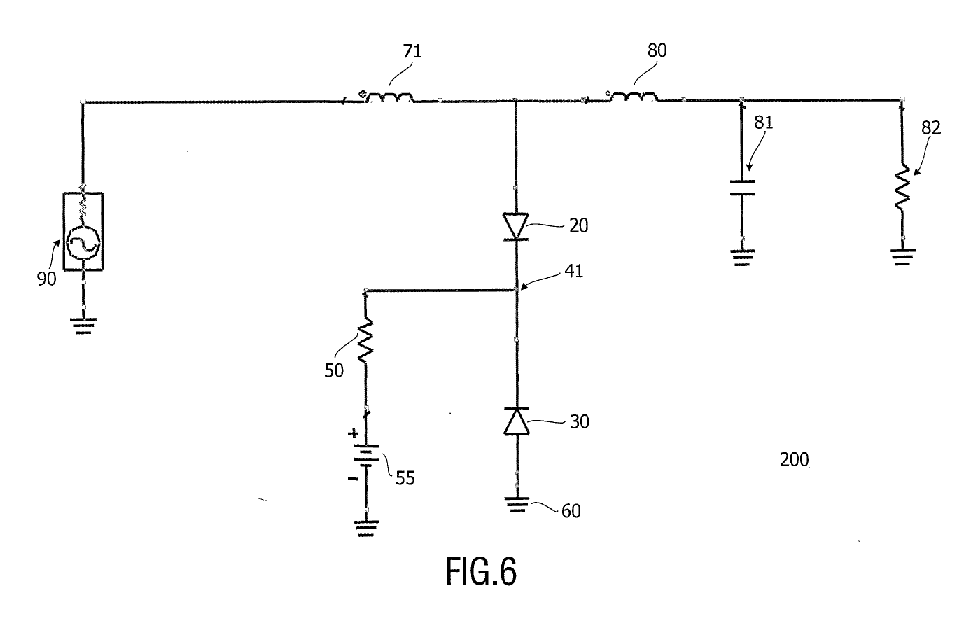

FIG. 6 shows as an example the electrical scheme of a simple adaptive impedance network with the arrangement as shown in FIGS. 1, 2 and 4;

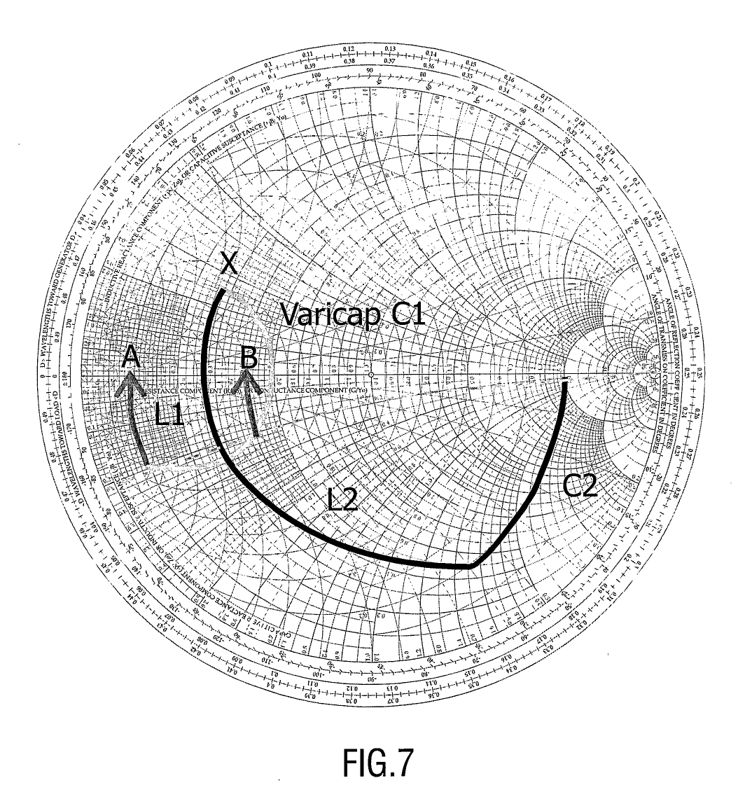

FIG. 7 shows a Smith's chart, which presents the effective impedance change of the matching network of FIG. 6 by tuning the varactor stack device;

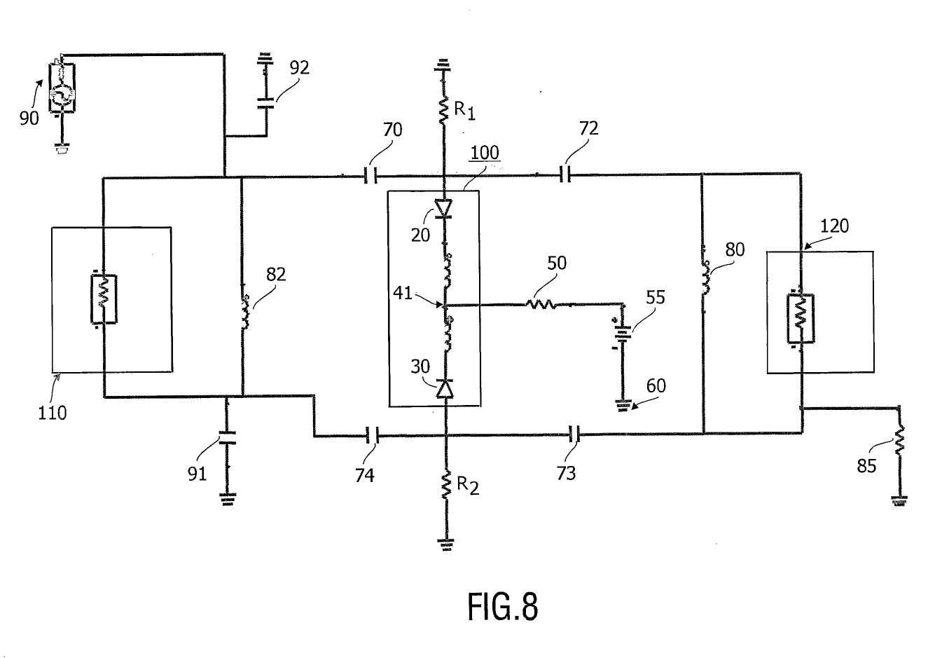

FIG. 8 shows an electrical scheme for a front end including a power amplifier, a low-noise amplifier and a balun; and

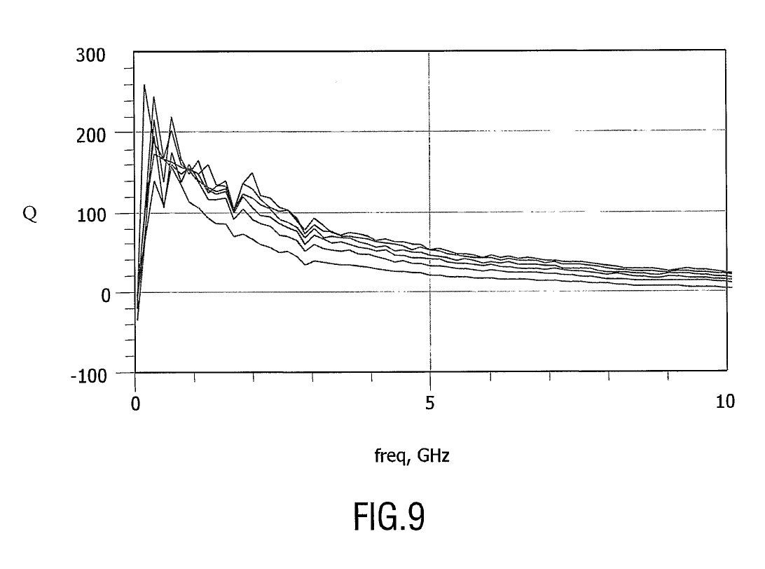

FIG. 9 shows a graph with measured data for the device of the invention.

The Figures are not drawn to scale. Similar or equal parts in different figures are referred to by equal reference numbers. Although the device shown is a discrete entity, it is to be understood that it is preferably integrated into a circuit with further components.

FIG. 1 shows a diagrammatic cross-sectional view of a first arrangement of the device 100 of the invention. The device 100 comprises a substrate 10 of a semiconductor material, in this case silicon, with a first side 11 and an opposite second side 12. The substrate comprises a highly doped layer 31, which is used as the first region. In this example, the first region 31 is p-type doped in a concentration of 1×10¹⁹ cm⁻³. It is therewith substantially electrically conductive. The first region 31 is preferably grown epitaxially, but it could be doped by implantation or diffusion or a combination thereof, as is known per se to a skilled person. The first region 31 has a contact 41. This is in this case a tungsten layer that is electrically connected to a resistor (not shown). It will be understood that this resistor could be integrated into the contact 41 by choosing a suitable resistor material such as SiCr or NiCr as the contact 41. Alternatively, the resistor could be integrated in the semiconductor substrate 10. The contact 41 is provided on the first side 11 of the substrate 10 after definition of the second region 32 and the third region 33. Use is made herein of conventional photolithography.

The second region 32 and the third region 33 are grown epitaxially in a layer thickness of about 0.5 μm in this example. The dopant concentration is 1×10¹⁷ cm⁻³. The dopant is of the opposite conductivity type to the dopant of the first region 31, and in this case n-type. The second region 32 and the third region 33 are defined at a mutual distance of 2.0 μm. A first junction 20 is defined between the first region 31 and the second region 32. A second junction 30 is defined between the first region 31 and the third region 33. Due to the uniform distribution of dopants, the junctions 20,30 are abrupt. The junctions 20,30 form the core of the first and second varactor diodes. They are put in an anti-series configuration, which is the effect of the contact 41. The areas of the junctions 20,30 are equal to each other so as to provide a device that is highly symmetric. In order to function as part of a tunable filter, the second region 32 is connected to a signal and the third region 33 is connected to ground.

The substrate 10 is preferably high-ohmic, with a resistance of more than 1 kΩ/cm. Such a high-ohmic substrate is suitable for the definition of inductors and capacitors in particular. In order to limit the diffusion of charge carrier from the varactor diodes into the substrate, it is suitable to provide isolation. Such isolation is for instance a cavity of insulating material, and can be made by providing vertical trenches in the substrate and by defining a buried oxide. Such buried oxide can be obtained while using a silicon-on-insulator substrate, but alternatively by implanting a layer with the SIMOX technique.

FIG. 2 is a graph in which the Q-factor and series resistance Rₛ versus Control Voltage are shown for the device as shown in FIG. 1. The line running from top left to bottom right shows the series resistance Rₛ and the line running from bottom left to top right shows the Q-factor. The control voltage is applied to the center contact 41 to provide the proper reverse bias conditions of the varactor diodes. Since the series resistance of the varactor diode is dominated by the non-depleted region of the varactor, the lowest Q will be found for low reverse bias voltage conditions, when there is almost no depletion in the varactor diodes. On increase of the control voltage, the non-depleted region will become smaller and, and hence the series resistance will decrease, whereas the Q factor increases.

FIG. 3 is a diagrammatic cross-sectional view of a second embodiment of the device of the invention. While FIG. 1 shows a configuration in which the varactor diodes are positioned laterally with respect to each other, this embodiment is a stacked configuration of varactor diodes. As a consequence of the stacking and the need to provide a center contact 41, the junction area of the first junction 20 is smaller than that of the second junction 30. The ratio is here about 1:4. The third region 33 is herein connected to a contact 42 to ground via a path 34, which is a highly doped substrate zone. As an alternative to such a contact 42, the grounding may be present on the second side 12 of the substrate 10, and a via to this second side 12 can be provided in the substrate 10. The manufactured device is n-doped in the second and third regions 32, 33 and p-type doped in the first region 31. The opposite doping is also possible, but requires more difficult manufacturing to obtain a sufficiently abrupt junction. The second region, first region and third region have a thickness of 0.5 μm, 0.1 μm and 0.5 μm respectively. A thinner p-type doped first region 31 is possible, however preferably in combination with a recombination layer, for instance of SiGe. Barriers at the side edges may be needed in this case.

The layers are epitaxially grown. Use is made of AP/LPCVD in the ASM Epsilon One, a commercially available, lamp-heated, single wafer reactor. The layers were deposited at 700° C. using SiC₁₂H₂ and—optionally for the first region—GeH₄ as the precursors, B₂H₆ and PH₃ as the dopant sources and H₂ as the carrier gas. The path 34 is provided by a phosphorous implanted step. The wafer is first baked at 1150° C. for 90 s to remove the native oxide. This prebake also anneals the phosphorous implantation. To avoid the accumulation of phosphorous at the first side 11 leading to severe autodoping, the prebake is performed at low pressure (60 Torr) and with a high H₂ flow (50 slm), followed by the deposition of a 10 nm undoped Si layer at 700° C. These prebake conditions stimulate the phosphorous desorption from the surface. During the low-temperature deposition the phosphorous incorporation is high, whereas the solid-state diffusion from the bulk and the segregation to the surface are low.

Subsequently, said layers were grown. Undoped Si layers with a thickness of 5 nm were inserted for dopant decoupling. The abruptness of the junctions is preferably of the order of a decade change in the conductivity per 2-3 nm. This leads to an intermediate area between the p-doped and the n-doped regions of about 10 nm. However, the abruptness is less critical to the extent that this intermediate area could even have a thickness of about 50 nm.

The contact to the second region 32 is formed in that a highly doped zone is grown as part of the epitaxially grown second region, on top of which a layer of Al or Al alloy such as Al_{0.99}Si_{0.01} is provided. This is done in conventional manner.

The contact 41 to the first region 31 is formed with laser annealing. This technique comprises four major steps. First, a mask is provided and patterned so as to expose the area of the contact 41. This mask is two-layered in this example and comprises a first layer of 300 nm thermal SiO₂ and a second layer of 600 nm Al_{0.99}Si_{0.01}. Alternatives for both layers, such as polysilicon for the second layer, can be envisaged. In the second step, an implantation is carried out, after a dip etch in 0.55% HF during three minutes to remove the native oxide in the contact window along with about 200 nm of the Al_{0.99}Si_{0.01}. The implantation is carried out for instance with BF₂⁺ at 5 keV and a dose of 10¹⁵ cm⁻². Hereafter, laser annealing is carried out with an energy in the range from 900 to 1100 mJ/cm². Experiments were performed using an XMR 5121 laser built into the XMR 7100 system. This system has an XeCl excimer laser (λ=308 nm) that is operated at an energy of around 500 mJ/pulse. The full width at half maximum is 60 ns and the repetition rate is 30 Hz. The maximum spot size is 10×10 mm² and can be adjusted to obtain the desired energy density. The annealing process is performed in a vacuum chamber at a pressure below 10⁻⁷ Torr and at room temperature. By using a beam homogenizer, the uniformity of the laser beam intensity is about 10% within a 10×10 mm² beam area. The last step of the provision of the contact 41 comprises the actual deposition of metal, for instance 500 nm Al_{0.99}Si_{0.01}, after the second layer of the mask has been removed in an etch step in the said HF solution. An anneal at 400° C. and lasting 30 minutes long is carried out after the deposition.

For the contact 42 to the path 34 use can be made of laser annealing or, alternatively, of silicidation or direct metallization. Also alternative methods for provision of a low-ohmic contact may be used, preferably with a resistance of less than 10⁻⁶ Ωcm/.

The resulting diode has a capacity of about 0.5 fF/μm². A capacity in the range from 1-50 pF is chosen, in this case 20 pF. This enables a variation of the capacity with a factor 2.5 depending on the voltage on the center contact, and ranging between 8 and 20 pF.

FIG. 4 shows a diagrammatic cross-sectional view of a third embodiment of the device of the invention. The device shown 100 is a lateral device. In this case, the first region 31 comprises a metal, and the resulting diodes are Schottky diodes. Moreover, low-ohmic contacts 42, 43 to the second region 32 and to the third region 33 are established by at least partial removal of the substrate 10 in a substrate transfer technique known per se. This technique is disclosed for instance in U.S. Pat. No. 5,504,036 for the opening of bond pads through the substrate, which patent specification is included herein by reference.

It will be understood that the combination of the Schottky diode with the substrate transfer technique provides good results and manufacturability; however, neither is excluded that the substrate transfer technique is applied in combination with a first region 31 of a semiconductor material; nor is excluded that Schottky diodes with alternative contacts are used. Not shown herein is the contact to the first region 31. The structure is stabilized with dielectric material (not shown).

FIG. 5a shows an electric scheme of a simple two-stage matching network 200 comprising the double varactor 100 of the invention. The input of the first diode 20 is connected to a DC Block capacitor 70 and to a DC Feed Inductance 80. The voltage source 90 has an impedance of 50Ω, and allows frequencies of 0.95 GHz and 1.05 GHz. The input of the second diode 30 is connected to ground 60. The center contact 41 is connected to the high-ohmic resistor 50, in this case having a resistance of 10 MΩ. All the element values are constant with the exception of capacitance of the varactor device 100. The adaptive matching network 200 has a 1:4 tuning range of R_{load}50. The tuning is implemented through the use of a single control voltage. Intermediate values of R_{load}50 are possible if one accepts a small imaginary error in the matching. The transistor 55 has an impedance of a few ohms and an output power of 1 W divided over two tones of 0.5 W (27 dBm). The varactor device 100 is present in the low impedance part of the adaptive matching network 200 in this example, but this is not necessary. The chosen application requires the use of high-valued varactor devices 100 and results in a relatively low voltage swing therefore.

FIG. 5b shows the electrical configuration when two varactor stacks are combined to improve the voltage handling capabilities. The device 100 herein comprises varactors 220, 230 in addition to varactors 20,30. As the number of outputs 41, 241, 341 is increased, the number of resistors 50, 250, 350 is increased accordingly. All resistors have a resistance of 10 kΩ. The four varactors 20,30, 220, 230 are suitably integrated into a single device 100. The benefits of this configuration 200 in comparison with that of FIG. 5a in which a thicker epilayer is used, are the higher Q factor and a lower control voltage.

The matching network design is based on the Smith' chart as shown in FIG. 7. Here the crossings of the constant conductance circle of the varactor device 100 shown as a dash-dotted line with the constant reactance circle (indicated in as a dashed line) result in the ohmic matching conditions A and B. As can be noted, a ratio of 3 to 4 was chosen for A to B, but this can be changed quite easily. By shifting point X over the constant conductance circle (adapting C2 and L2) one can influence the ratio of the required varactor values and, consequently, the required control voltage range. By changing normalization impedance one can shift up and down in the impedance range.

FIG. 6 shows a more elaborate implementation of a matching network 200. In this example, the inductor 80 is connected to ground 60 through a parallel-switched capacitor 81 and resistor 82. The inductor has a value of 2.07 nH, the capacitor has a capacitance of 3.2 pF and the resistor has a value of 50Ω. Instead of the DC blocking capacitor a further inductor 71 of 0.475 nH is positioned between the voltage source 90 and the first diode. Here, the voltage source has an impedance of 3Ω. The resistor 50 is in this example 10 kΩ. The control voltage has been changed from 1 to 7, which results in a impedance change at port 1 by a factor 3. Please note that we can change these ratios to higher values, but for the moment we limit ourselves to the illustration of the basic principle. The related voltages for 1 W output power remain below 7V. The resulting levels of the third intermodulation distortion and higher harmonics are better than 65 dBc for a perfectly abrupt junction (identified through a grading coefficient M=0.5) and for the full control range. For a grading coefficient M=0.526, which corresponds to a standard SiGe BiCMOS process value, this number decreases to 55 dBc. The voltage-dependent series resistance of the varactor device 200 seems to have no significant influence on the linearity of the circuit.

FIG. 8 shows an electrical diagram of a balun comprising the varactor device 100 of the invention, a Low Noise Amplifier (LNA) 120 and a Power Amplifier (PA) 110. Capacitors 70,74 isolate the varactor device 100 from the PA 110; both have a value of 0.55 pF. They are coupled through an inductor 82 with an inductance of 0.98 nH. Both lines are connected to ground over capacitors 91,92 of 8.1 pF and over resistors R₁, R₂ of 100 kΩ. A voltage source 90 is provided as well. Capacitors 72,73 isolate the varactor device 100 from the LNA 120. The capacitors 72,73 have a value of 4.1 pF and are coupled through an inductor 3.89 nH. The varactor device provides an effective short on the transmit frequency when the PA is switched on. In this way the LNA is protected from too high voltage conditions caused by the PA. In the receive mode the PA is switched off and the varactor value is changed in such a way that the LNA is matched with the antenna.

FIG. 9 shows a graph with measured data for the device of the invention. Measurements were carried out for the device as diagrammatically shown in FIG. 4. The graph shows the Q-factor of the device as a function of the frequency for several driving voltages. The Q-factor decreases with frequency, which is a well-known frequency-dependent behavior for a capacitor. For the current RF activities, the spectrum between 0.8 and 2.4 GHz is most relevant. At 0.8 GHz the Q-factor is 100 or more for all the measured voltages. At 2.4 GHz the Q-factor is between 40 and 120 for the measured voltages. This behavior is excellent.

1. A semiconductor device comprising a first and a second varactor, which are connected in an anti-series configuration, such that a first substantially electrically conductive region is present between a second region with dopant of a first conductivity type and a third region with dopant of the first conductivity type, wherein:
the second and third regions comprise dopant that is distributed uniformly within the region, and
the first region is provided with or connected to a contact which has an AC resistance of at least 1 kΩ.

2. A semiconductor device as claimed in claim 1, wherein:
the second and third regions each have an interfacial area at an interface facing the first region, and
the interfacial areas of the second and third regions have sizes that have a mutual ratio of at most two.

3. A semiconductor device as claimed in claim 1, wherein the third region is grounded.

4. A semiconductor device as claimed in claim 1, wherein the first and the second varactors are varactor diodes, and junctions are present between the first and the second region and between the first and the third region.

5. A semiconductor device as claimed in claim 1, wherein the first and the second varactors are MOS varactors, and insulating layers are present between the first and the second region and between the first and the third region.

6. A semiconductor device as claimed in claim 1, wherein the first, second and third regions are present in a substrate of semiconductor material, said substrate having a resistivity of at least 500 Ω/cm, preferably more than 1 kΩ/cm.

7. A semiconductor device as claimed in claim 1, wherein the first and second varactor diodes are present as a variable capacitance within an impedance matching network.

8. A semiconductor device as claimed in claim 1, wherein first and second varactor diodes are present within a substrate area that is isolated from other areas of the substrate.

9. A semiconductor device as claimed in claim 4, further comprising a lateral pin-diode for use as band switch.

10. A semiconductor device as claimed in claim 1, wherein the first region comprises a semiconductor material and is doped with a dopant of a second conductivity type opposite to the first conductivity type.

11. A semiconductor device as claimed in claim 10, wherein the first region comprises a recombination layer of a material different from other layers in the first region.

12. A semiconductor device as claimed in claim 10, wherein the first, second and third regions are epitaxially grown regions.

13. A semiconductor device as claimed in claim 1, wherein the second and the third region have low-ohmic contact with a resistivity of at most 10⁻⁶ Ωcm/□.

14. A semiconductor device as claimed in claim 1, wherein the third region is coupled to a metallic contact obtainable for at least local substrate removal.

15. A semiconductor device as claimed in claim 1, wherein the resistance is present as a layer of a resistor material that is integrated in the device

16. A semiconductor device as claimed in claim 1, wherein the junctions have a thickness in which the dopant profile changes from the uniform doping level of the first conductivity type to the uniform doping level of the second conductivity type, which thickness is at most 50 nm and preferably less than 20 nm.

17. A semiconductor device as claimed in claim 10, wherein the ratio of the doping level of the first region and that of the second and third regions is at least 50 and preferably more than 100.
